(19) United States
(12) Patent Application Publication
(10) Pub. No.: US 2025/0390030 A1
(43) Pub. Date: Dec. 25, 2025

(54) TEMPERATURE CONTROLLING APPARATUS

(71) Applicant: NANYA TECHNOLOGY CORPORATION, New Taipei City (TW)

(72) Inventor: Jung Tzu PENG, New Taipei City (TW)

(21) Appl. No.: 18/752,748

(22) Filed: Jun. 24, 2024

(51) Int. Cl. G03F 7/00; G01J 5/00; G01J 5/08; G01J 5/48; G05D 23/19; G05D 23/27

(52) U.S. Cl. CPC G03F 7/70875; G01J 5/0859; G01J 5/485; G03F 7/70525; G03F 7/70716; G03F 7/7075; G03F 7/7085; G05D 23/1927; G05D 23/27; G01J 2005/0077

(57) ABSTRACT

A temperature controlling apparatus includes a thermal plate, a cover, at least one thermal sensor and an analyzing device. The cover is connected with the thermal plate to define a working space therebetween. The working space is configured to accommodate a wafer. The thermal plate is configured to support the wafer and adjust a first temperature of the wafer. The thermal sensor is disposed on the cover and configured to detect the first temperature. The analyzing device is signally connected with the thermal sensor and configured to receive a signal from the thermal sensor according to the first temperature detected. The analyzing device is further configured to analyze and obtain a magnitude of the first temperature from the signal received.

### BACKGROUND

### Technical Field

The present disclosure relates to temperature controlling apparatus. More particularly, the present disclosure relates to temperature controlling apparatus used for photolithography of wafers.

### Description of Related Art

As the demand for electronic devices has been increasing nowadays, the quality of various components of electronic devices becomes an important issue of the industry. Apart from improving the technology of manufacture of the components, the measures to guarantee the quality of the components during production is also highly concerned.

For example, in the process of photolithography, a wafer is maintained at a specific temperature in order to achieve a good processing result. Thus, the measure to maintain an even distribution of temperature of a wafer in the process of photolithography is undoubtedly an important issue in the industry.

### SUMMARY

A technical aspect of the present disclosure is to provide a temperature controlling apparatus, which can accurately monitor and instantly adjust the temperature at different portions of the wafer in real time, thus improving the effect of photolithography performed to the wafer.

According to an embodiment of the present disclosure, a temperature controlling apparatus includes a thermal plate, a cover, at least one thermal sensor and an analyzing device. The cover is connected with the thermal plate to define a working space therebetween. The working space is configured to accommodate a wafer. The thermal plate is configured to support the wafer and adjust a first temperature of the wafer. The thermal sensor is disposed on the cover and configured to detect the first temperature. The analyzing device is signally connected with the thermal sensor and configured to receive a signal from the thermal sensor according to the first temperature detected. The analyzing device is further configured to analyze and obtain a magnitude of the first temperature from the signal received.

In one or more embodiments of the present disclosure, a quantity of the thermal sensor is plural. The thermal sensors are evenly distributed on the cover.

In one or more embodiments of the present disclosure, one of the thermal sensors is located at a center, and other ones of the thermal sensors are evenly distributed around the center.

In one or more embodiments of the present disclosure, the thermal plate has a supporting surface communicated with the working space. The supporting surface is configured to support the wafer.

In one or more embodiments of the present disclosure, the thermal sensor is separated from the supporting surface by a distance. The distance is larger than a thickness of the wafer.

In one or more embodiments of the present disclosure, the supporting surface is divided into a plurality of thermal zones connected with each other. The temperature controlling apparatus further includes a processing unit. The processing unit is signally connected with the analyzing device and the thermal zones. The processing unit is configured to adjust a second temperature of at least one of the thermal zones according to the first temperature obtained by the analyzing device.

In one or more embodiments of the present disclosure, the thermal zones include a circular zone and a plurality of annular zones concentrically arranged with the circular zone.

In one or more embodiments of the present disclosure, each of the thermal zones is shaped as a sector. The sectors are circularly arranged.

In one or more embodiments of the present disclosure, the thermal zones include a central zone and a plurality of peripheral zones circularly arranged around the central zone.

In one or more embodiments of the present disclosure, the temperature controlling apparatus further includes a handling device. The handling device is signally connected with the processing unit and configured to move the wafer into or out of the working space.

In one or more embodiments of the present disclosure, the second temperature is ranged between 10 and 300 degree Celsius.

In one or more embodiments of the present disclosure, the thermal sensor is an infra-red camera.

According to an embodiment of the present disclosure, a temperature controlling apparatus includes a thermal plate, a cover, a plurality of infra-red cameras, an analyzing device and a processing unit. The thermal plate has a plurality of thermal zones. The cover is connected with the thermal plate to define a working space therebetween. The working space is communicated with the thermal zones and configured to accommodate a wafer. The thermal plate is configured to support the wafer and adjust a first temperature of the wafer. The infra-red cameras are evenly disposed on the cover and respectively configured to detect the first temperature. The analyzing device is signally connected with the infra-red cameras and configured to receive a signal from each of the infra-red cameras according to a corresponding one of the first temperatures detected. The analyzing device is configured to analyze and obtain a magnitude of each of the first temperatures from the signals received. The processing unit is signally connected with the analyzing device and the thermal zones. The processing unit is configured to adjust a second temperature of at least one of the thermal zones according to the first temperatures obtained by the analyzing device.

In one or more embodiments of the present disclosure, one of the infra-red cameras is located at a center, and other ones of the infra-red cameras are evenly distributed around the center.

In one or more embodiments of the present disclosure, a distance between each of the infra-red cameras and the thermal plate is larger than a thickness of the wafer.

In one or more embodiments of the present disclosure, the thermal zones include a circular zone and a plurality of annular zones concentrically arranged with the circular zone.

In one or more embodiments of the present disclosure, each of the thermal zones is shaped as a sector. The sectors are circularly arranged.

In one or more embodiments of the present disclosure, the thermal zones include a central zone and a plurality of peripheral zones circularly arranged around the central zone.

In one or more embodiments of the present disclosure, the temperature controlling apparatus further includes a handling device. The handling device is signally connected with the processing unit and configured to move the wafer into or out of the working space.

In one or more embodiments of the present disclosure, each of the second temperatures is ranged between 10 and 300 degree Celsius.

The above-mentioned embodiments of the present disclosure have at least the following advantages:

(1) Since there is a plurality of the thermal sensors disposed on the cover and the thermal sensors are evenly distributed, each of the thermal sensors can be in correspondence with different portions of the wafer. In other words, each of the thermal sensors can detect the first temperature with respect to different portions of the wafer. In this way, when the thermal plate is adjusting the first temperature of the wafer, the first temperature at different portions of the wafer can be accurately known and monitored in real time.

(2) Since the processing unit is signally connected with the thermal zones on the supporting surface of the thermal plate and is configured to adjust a second temperature of at least one of the thermal zones according to the first temperatures obtained by the analyzing device in real time, a consistency of the first temperatures at different portions of the wafer can be instantly and effectively achieved, which facilitates the effect of photolithography performed to the wafer.

### BRIEF DESCRIPTION OF THE DRAWINGS

The disclosure can be more fully understood by reading the following detailed description of the embodiments, with reference made to the accompanying drawings as follows:

FIG. 1 is a schematic view of a temperature controlling apparatus according to an embodiment of the present disclosure;

FIG. 2 is a cross-sectional view along the section line A-A of FIG. 1;

FIG. 3 is a cross-sectional view along the section line B-B of FIG. 1;

FIG. 4 is a cross-sectional view along the section line B-B of FIG. 1 according to another embodiment of the present disclosure; and

FIG. 5 is a cross-sectional view along the section line B-B of FIG. 1 according to a further embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

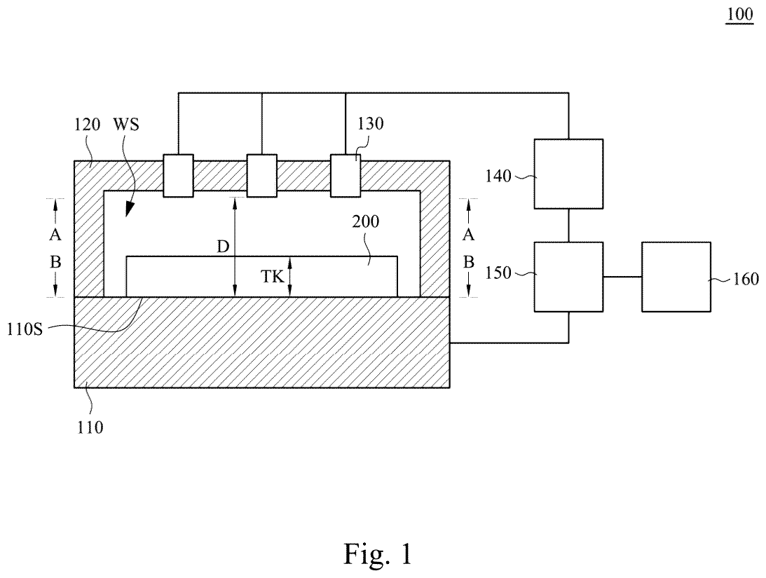

Reference is made to FIG. 1. FIG. 1 is a schematic view of a temperature controlling apparatus 100 according to an embodiment of the present disclosure. In this embodiment, as shown in FIG. 1, a temperature controlling apparatus 100 used for photolithography of wafers 200 is provided. The temperature controlling apparatus 100 includes a thermal plate 110, a cover 120, at least one thermal sensor 130, an analyzing device 140 and a processing unit 150. The cover 120 is connected with the thermal plate 110 to define a working space WS therebetween. The working space WS is configured to accommodate a wafer 200. The thermal plate 110 is configured to support the wafer 200 and adjust a first temperature of the wafer 200. The thermal sensor 130 is disposed on the cover 120 and configured to detect the first temperature of the wafer 200. The analyzing device 140 is signally connected with the thermal sensor 130 and configured to receive a signal from the thermal sensor 130 according to the first temperature detected. The analyzing device 140 is further configured to analyze and obtain a magnitude of the first temperature from the signal received. The processing unit 150 is signally connected with the analyzing device 140 and the thermal plate 110. In practice, for example, the thermal sensor 130 is an infra-red camera.

Furthermore, as shown in FIG. 1, the thermal plate 110 has a supporting surface 110S communicated with the working space WS. The supporting surface 110S of the thermal plate 110 is configured to support the wafer 200.

In addition, as shown in FIG. 1, the thermal sensor 130 is separated from the supporting surface 110S of the thermal plate 110 by a distance D. It is worth to note that, in this embodiment, the distance D between the thermal sensor 130 and the supporting surface 110S is larger than a thickness TK of the wafer 200. In this way, the thermal sensor 130 is separated from the wafer 200. In other words, the thermal sensor 130 does not contact with the wafer 200.

Moreover, in this embodiment, as shown in FIG. 1, the temperature controlling apparatus 100 further includes a handling device 160. The handling device 160 is signally connected with the processing unit 150 and configured to move the wafer 200 into or out of the working space WS.

As mentioned above, since the magnitude of the first temperature of the wafer 200 can be obtained by the analyzing device 140, the actual condition of how the thermal plate 110 is adjusting the first temperature of the wafer 200 can be monitored in real time.

In practice, as shown in FIG. 1, a quantity of the thermal sensor 130 is plural. Furthermore, in this embodiment, the thermal sensors 130 are evenly distributed on the cover 120.

To be more specific, since there is a plurality of the thermal sensors 130 disposed on the cover 120 and the thermal sensors 130 are evenly distributed, each of the thermal sensors 130 can be relatively closer to and in correspondence with different portions of the wafer 200. In other words, each of the thermal sensors 130 can detect the first temperature with respect to different portions of the wafer 200. In this way, when the thermal plate 110 is adjusting the first temperature of the wafer 200, the first temperature at different portions of the wafer 200 can be accurately known and monitored in real time.

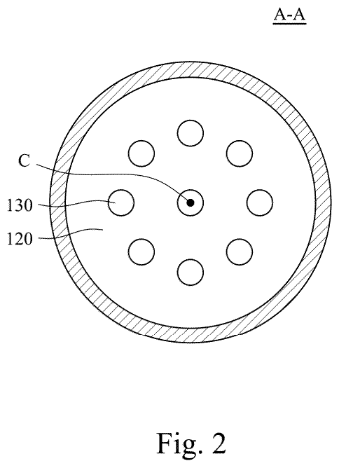

Reference is made to FIG. 2. FIG. 2 is a cross-sectional view along the section line A-A of FIG. 1. As mentioned above, a plurality of the thermal sensors 130 is evenly distributed on the cover 120. For example, in this embodiment, as shown in FIG. 2, one of the thermal sensors 130 is located at a center C, and other ones of the thermal sensors 130 are circularly arranged and evenly distributed around the center C.

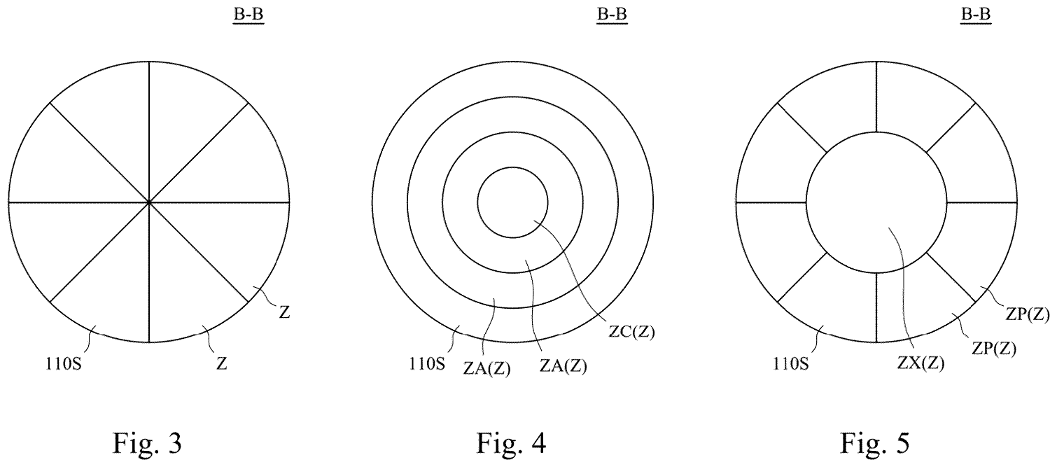

Reference is made to FIG. 3. FIG. 3 is a cross-sectional view along the section line B-B of FIG. 1. In practical applications, the supporting surface 110S is divided into a plurality of thermal zones Z connected with each other. For example, in this embodiment, as shown in FIG. 3, each of the thermal zones Z is shaped as a sector and the sectors are circularly arranged. Each of the thermal zones Z is configured to be in direct contact with the wafer 200 and to be controlled to reach a second temperature by, for example, a corresponding temperature adjusting element (not shown). In other words, the second temperature of each of the thermal zones Z is used to adjust the first temperature of different portions of the wafer 200. Therefore, the first temperature of each portion of the wafer 200 will finally reach the second temperature of the thermal zone Z to which this portion of the wafer 200 is directly connected.

Furthermore, as shown in FIG. 1, the processing unit 150 is signally connected with the thermal plate 110. To be specific, the processing unit 150 is signally connected with temperature adjusting elements thermally and respectively connected with the thermal zones Z (please see FIG. 3 for the thermal zones Z) on the supporting surface 110S of the thermal plate 110. In practice, the processing unit 150 is configured to adjust a second temperature of at least one of the thermal zones Z according to the first temperatures obtained by the analyzing device 140 in real time. Therefore, a consistency of the first temperatures at different portions of the wafer 200 can be instantly and effectively achieved, which facilitates the effect of photolithography performed to the wafer 200. For example, the second temperature, controlled by a corresponding temperature adjusting element, of each of the thermal zones Z is ranged between 10 and 300 degree Celsius. However, this does not intend to limit the present disclosure.

In sum, during the operation of the temperature controlling apparatus 100, the wafer 200 is first moved into the working space WS by the handling device 160 and supported by the supporting surface 110S of the thermal plate 110. Each of the thermal zones Z on the supporting surface 110S is then heated up or cooled down by a corresponding temperature adjusting element, such that the second temperature of each of the thermal zones Z is adjusted. Correspondingly, the first temperature of each portion of the wafer 200 will reach the second temperature of the thermal zone Z to which each of these portions of the wafer 200 is directly connected. At the same time, each of the thermal sensors 130 detects the first temperature with respect to different portions of the wafer 200 while the analyzing device 140 receives signals from the thermal sensors 130 according to the first temperatures detected and obtains a magnitude of each of the first temperatures from the signals received. In this way, the first temperature at different portions of the wafer 200 are accurately known and monitored in real time. However, for example, in case one of the first temperatures obtained by the analyzing device 140 is obviously different from other first temperatures obtained, the processing unit 150 signally connected with the analyzing device 140 and the thermal zones Z will corresponding adjust the second temperature of this particular thermal zone Z, such that the consistency of the first temperatures at different portions of the wafer 200 can be instantly maintained, which facilitates the effect of photolithography performed to the wafer 200.

Reference is made to FIG. 4. FIG. 4 is a cross-sectional view along the section line B-B of FIG. 1 according to another embodiment of the present disclosure. In this embodiment, as shown in FIG. 4, the thermal zones Z include a circular zone ZC and a plurality of annular zones ZA. The annular zones ZA are concentrically arranged with the circular zone ZC.

Reference is made to FIG. 5. FIG. 5 is a cross-sectional view along the section line B-B of FIG. 1 according to a further embodiment of the present disclosure. In this embodiment, as shown in FIG. 5, the thermal zones Z include a central zone ZX and a plurality of peripheral zones ZP circularly arranged around the central zone ZX.

In conclusion, the aforementioned embodiments of the present disclosure have at least the following advantages:

(1) Since there is a plurality of the thermal sensors disposed on the cover and the thermal sensors are evenly distributed, each of the thermal sensors can be in correspondence with different portions of the wafer. In other words, each of the thermal sensors can detect the first temperature with respect to different portions of the wafer. In this way, when the thermal plate is adjusting the first temperature of the wafer, the first temperature at different portions of the wafer can be accurately known and monitored in real time.

(2) Since the processing unit is signally connected with the thermal zones on the supporting surface of the thermal plate and is configured to adjust a second temperature of at least one of the thermal zones according to the first temperatures obtained by the analyzing device in real time, a consistency of the first temperatures at different portions of the wafer can be instantly and effectively achieved, which facilitates the effect of photolithography performed to the wafer.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A temperature controlling apparatus, comprising:
a thermal plate;
a cover connected with the thermal plate to define a working space therebetween, the working space being configured to accommodate a wafer, the thermal plate being configured to support the wafer and adjust a first temperature of the wafer;
at least one thermal sensor disposed on the cover and configured to detect the first temperature; and
an analyzing device signally connected with the thermal sensor and configured to receive a signal from the thermal sensor according to the first temperature detected, and the analyzing device is further configured to analyze and obtain a magnitude of the first temperature from the signal received.

2. The temperature controlling apparatus of claim 1, wherein a quantity of the thermal sensor is plural, the thermal sensors are evenly distributed on the cover.

3. The temperature controlling apparatus of claim 2, wherein one of the thermal sensors is located at a center, and other ones of the thermal sensors are evenly distributed around the center.

4. The temperature controlling apparatus of claim 1, wherein the thermal plate has a supporting surface communicated with the working space, the supporting surface is configured to support the wafer.

5. The temperature controlling apparatus of claim 4, wherein the thermal sensor is separated from the supporting surface by a distance, the distance is larger than a thickness of the wafer.

6. The temperature controlling apparatus of claim 4, wherein the supporting surface is divided into a plurality of thermal zones connected with each other,
the temperature controlling apparatus further comprises:
a processing unit signally connected with the analyzing device and the thermal zones, the processing unit is configured to adjust a second temperature of at least one of the thermal zones according to the first temperature obtained by the analyzing device.

7. The temperature controlling apparatus of claim 6, wherein the thermal zones include a circular zone and a plurality of annular zones concentrically arranged with the circular zone.

8. The temperature controlling apparatus of claim 6, wherein each of the thermal zones is shaped as a sector, the sectors are circularly arranged.

9. The temperature controlling apparatus of claim 6, wherein the thermal zones include a central zone and a plurality of peripheral zones circularly arranged around the central zone.

10. The temperature controlling apparatus of claim 6, further comprising:
a handling device signally connected with the processing unit and configured to move the wafer into or out of the working space.

11. The temperature controlling apparatus of claim 6, wherein the second temperature is ranged between 10 and 300 degree Celsius.

12. The temperature controlling apparatus of claim 1, wherein the thermal sensor is an infra-red camera.

13. A temperature controlling apparatus, comprising:
a thermal plate having a plurality of thermal zones;
a cover connected with the thermal plate to define a working space therebetween, the working space being communicated with the thermal zones and configured to accommodate a wafer, the thermal plate being configured to support the wafer and adjust a first temperature of the wafer;
a plurality of infra-red cameras evenly disposed on the cover and respectively configured to detect the first temperature;
an analyzing device signally connected with the infra-red cameras and configured to receive a signal from each of the infra-red cameras according to a corresponding one of the first temperatures detected, the analyzing device is configured to analyze and obtain a magnitude of each of the first temperatures from the signals received; and
a processing unit signally connected with the analyzing device and the thermal zones, the processing unit is configured to adjust a second temperature of at least one of the thermal zones according to the first temperatures obtained by the analyzing device.

14. The temperature controlling apparatus of claim 13, wherein one of the infra-red cameras is located at a center, and other ones of the infra-red cameras are evenly distributed around the center.

15. The temperature controlling apparatus of claim 13, wherein a distance between each of the infra-red cameras and the thermal plate is larger than a thickness of the wafer.

16. The temperature controlling apparatus of claim 13, wherein the thermal zones include a circular zone and a plurality of annular zones concentrically arranged with the circular zone.

17. The temperature controlling apparatus of claim 13, wherein each of the thermal zones is shaped as a sector, the sectors are circularly arranged.

18. The temperature controlling apparatus of claim 13, wherein the thermal zones include a central zone and a plurality of peripheral zones circularly arranged around the central zone.

19. The temperature controlling apparatus of claim 13, further comprising:
a handling device signally connected with the processing unit and configured to move the wafer into or out of the working space.

20. The temperature controlling apparatus of claim 13, wherein each of the second temperatures is ranged between 10 and 300 degree Celsius.
